(19) United States
(12) Patent Application Publication
(10) Pub. No.: US 2013/0099870 A1
(43) Pub. Date: Apr. 25, 2013

(54) VOLTAGE CONTROLLED OSCILLATORS HAVING LOW PHASE NOISE

(71) Applicant: Emmanouil Terrovitis, Foster City, CA (US)

(72) Inventor: Emmanouil Terrovitis, Foster City, CA (US)

(73) Assignee: Qualcomm Atheros, Inc., San Jose, CA (US)

(21) Appl. No.: 13/278,052

(22) Filed: Oct. 20, 2011

(51) Int. Cl. H03B 1/00

(52) U.S. Cl. 331/56

(57) ABSTRACT

This disclosure involves systems for providing an oscillatory circuit having low phase noise featuring arrays of complementary VCO pairs connected in parallel.

### FIELD OF THE PRESENT INVENTION

The present disclosure generally relates to voltage controlled oscillators (VCOs) and more particularly to integrated inductor-capacitor tank VCOs (LC VCOs) having low phase noise.

### BACKGROUND OF THE INVENTION

Voltage controlled oscillators (VCOs) are an important class of circuits widely used in modern electronic devices. For example, phase locked loops (PLLs) employing VCOs are used to isolate and demodulate signals and synthesize frequencies in wireless communication applications as well as provide critical timing functions in computing processors and data streams. As the name implies, the frequency output of a VCO may be tuned by varying the voltage applied to the circuit. A commonly used type of harmonic VCO utilizes a resonant circuit formed by inductors and capacitors and correspondingly is known as an LC VCO.

As integrated circuit (IC) manufacturing techniques have matured, a greater number of circuit elements have been implemented directly on the chip, avoiding the costs and complications associated with providing such elements as discrete items. These trends are exemplified by the development of system on a chip (SoC) and application specific IC (ASIC) technologies, in which multiple aspects of an electronic system, including analog, digital, mixed and RF functions, are integrated into a single chip. Given the importance of VCOs, there is a corresponding need to effectively incorporate such circuits into ICs using the semiconductor manufacturing processes. Accordingly, VCOs suitable for incorporation into an IC typically involve a substantially planar inductor coil formed from one or more metal layers in the IC. However, especially at higher frequencies, such as those associated with wireless communication, several challenges regarding the design of integrated VCOs exist.

In particular, phase noise is a frequency domain characteristic that corresponds to jitter in the time domain and can be considered an undesirable modulation of the VCO's oscillation frequency. Phase noise impacts many aspects of systems employing VCOs, including mixing performance, noise floor, noise transmission, interference and bit error rate depending on the type of system. Thus, phase noise is an important parameter of VCOs that must be minimized to obtain a desired level of performance. Thus, there is a need to provide VCO designs suitable for incorporation into ICs that have low phase noise. The systems of this disclosure satisfy these and other needs.

### SUMMARY OF THE INVENTION

In accordance with the above objects and those that will be mentioned and will become apparent below, this disclosure is directed to a an oscillatory array having a first pair of integrated VCOs wherein each VCO includes resonant circuit elements and an inductor formed from a single turn coil positioned on a substantially planar substrate and wherein the VCOs are connected in parallel. Preferably, each of the first pair of VCOs are positioned adjacent each other in the same plane. Also preferably, at least one segment of the single turn coil of each VCO is shared. In such embodiments, the shared segment portion of the single turn coil is at least approximately 25% of each single turn coil. Another preferred embodiment is directed to the VCOs having opposing flux polarities.

In one aspect of the disclosure, the resonant circuit elements of each VCO are positioned within an area defined by the single turn coil of each VCO and substantially within the same plane. Preferably, a plurality of interconnects are formed in a lower metal layer of the semiconductor substrate underneath the single turn coil of each VCO and the interconnects are in electrical communication with the resonant circuit elements of each VCO.

In another embodiment, the oscillatory array also includes a second pair of VCOs, wherein each VCO of the second pair includes resonant circuit elements and an inductor formed from a single turn coil positioned on the substantially planar substrate positioned adjacent the first pair of VCOs in substantially the same plane and wherein the second pair of VCOs are connected in parallel with the first pair of VCOs. Preferably, segments of the single turn coils of the first pair of VCOs are shared with segments of the single turn coils of the second pair of VCOs. As desired, the shared segment portion of the single turn coil can be at least approximately 25% of each single turn coil. Further, the resonant circuit elements of each VCO of the second pair can be positioned within an area defined by the single turn coil of each VCO and substantially within the same plane. In another preferred aspect, each VCO of the first pair and the second pair has at least two neighboring VCOs having opposing flux polarities.

Yet another aspect of the disclosure is directed to an oscillatory array comprising multiple integrated VCOs wherein each VCO includes resonant circuit elements and an inductor formed from a single turn coil positioned on a substantially planar substrate and wherein the VCOs are connected in parallel. Preferably, the VCOs are positioned adjacent one another in a symmetrical grid configuration. In one embodiment, the oscillatory array has 16 VCOs.

In another embodiment, each VCO shares at least one segment of the single turn coil with at least one segment of the single turn coil of at least two neighboring VCOs and further, at least one VCO shares at least one segment of the single turn coil with at least one segment of the single turn coil of at least four neighboring VCOs. Preferably, the shared segment portion of the at least one VCO is at least approximately 25% of the single turn coil.

In yet another embodiment, each VCO has at least two neighboring VCOs having opposing flux polarities and further, at least one VCO has at least four neighboring VCOs having opposing flux polarities.

### BRIEF DESCRIPTION OF THE DRAWINGS

Further features and advantages will become apparent from the following and more particular description of the preferred embodiments of the invention, as illustrated in the accompanying drawing, and in which like referenced characters generally refer to the same parts or elements throughout the views, and in which:

FIG. 1 is a schematic diagram of a LC VCO suitable for use with the invention;

FIG. 2 is a schematic diagram of a pair of LC VCOs forming an oscillatory array; according to the invention, and

FIG. 3 is a schematic diagram of an array of 16 LC VCOs, according to the invention.

### DETAILED DESCRIPTION OF THE INVENTION

At the outset, it is to be understood that this disclosure is not limited to particularly exemplified materials, methods or structures as such may, of course, vary. Thus, although a number of materials and methods similar or equivalent to those described herein can be used in the practice of embodiments of this disclosure, the preferred materials and methods are described herein.

It is also to be understood that the terminology used herein is for the purpose of describing particular embodiments of this disclosure only and is not intended to be limiting.

Unless defined otherwise, all technical and scientific terms used herein have the same meaning as commonly understood by one having ordinary skill in the art to which the disclosure pertains.

Further, all publications, patents and patent applications cited herein, whether supra or infra, are hereby incorporated by reference in their entirety.

Finally, as used in this specification and the appended claims, the singular forms “a, “an” and “the” include plural referents unless the content clearly dictates otherwise.

This disclosure is directed to integrated VCO configurations that feature low phase noise. LC VCOs are commonly used for RF applications because they have a lower phase noise than other inductor-less VCO topologies. Nevertheless, the performance of devices employing LC VCOs can still be improved by further minimizing their phase noise. As will be described in detail below, the inventive VCO arrays feature inductor designs suitable for implementation on-chip in ICs and result in oscillators having reduced phase noise.

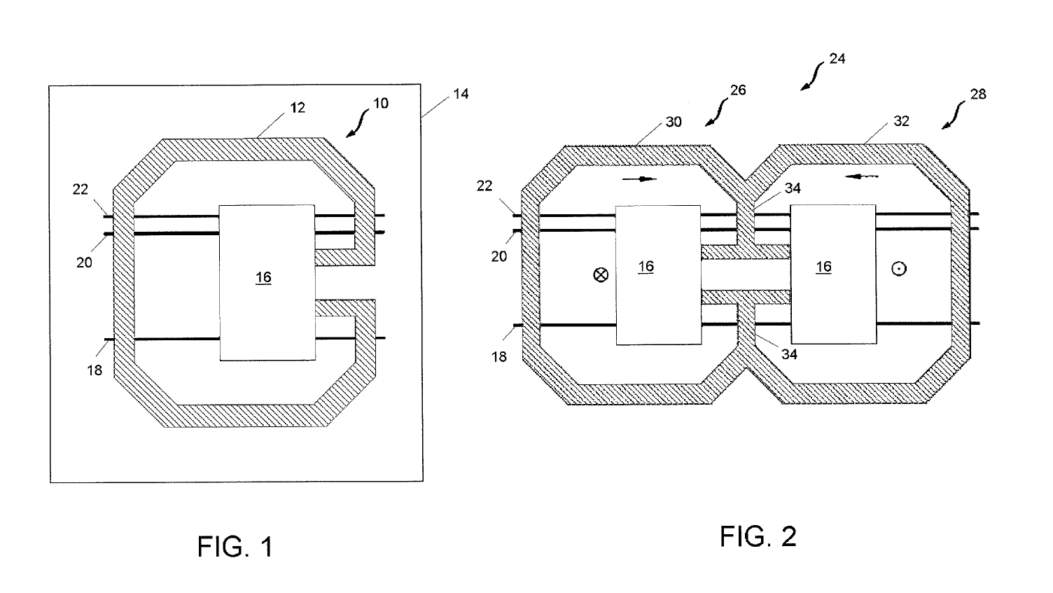

Turning to FIG. 1, a VCO 10 suitable for use in the embodiments of this disclosure is shown schematically and generally includes a single turn inductor coil 12 formed in an upper metal layer of an IC having a semiconductor substrate 14. Resonant circuit elements 16 are positioned within the area defined by coil 12. As will be appreciated, depending upon the design of the particular LC tank circuit used to drive VCO 10, circuit elements 16 can include transistors, capacitors, varactors and the like. Further, these circuit elements 16 are preferably formed using conventional semiconductor manufacturing techniques. Interconnects 18, 20 and 22 are preferably formed in metal layers below the coil 12 and provide suitable connections for supply lines, control signals and the like. If desired, interconnects 18-22 can also provide the necessary connections to the oscillator output.

As shown in FIG. 1, inductor coil 12 has a substantially square configuration with four primary sides and angled corners. In other embodiments, suitable shapes for the coil can include substantially circular, true square, rectangular or polygonal geometries as desired.

Phase noise for an LC VCO is often modeled using Leeson's equation. One formulation of this equation is:

$${L}_{PM} = 10 log [ \frac{FkT}{A} \frac{1}{8 {Q}_{R}^{2}} {( \frac{{f}_{0}}{{f}_{m}} )}^{2} ] \qquad ( 1 )$$

in which
L_{PM} is single-sideband phase noise density
F is the device noise factor at operating power level A
k is Boltzmann's constant, 1.38×10⁻²³ J/K
T is temperature
A is oscillator output power
Q_{R} is loaded Q
fₒ is the oscillator carrier frequency
fₘ is the frequency offset from the carrier.

In particular, Q_{R} is the quality factor for the LC resonant circuit and depends upon the ratio of the energy stored to the energy dissipated in the circuit per oscillation cycle. From Equation (1), it is evident that phase noise is inversely related to Q_{R}. As such, phase noise can be minimized by selecting inductor designs that have a high quality factor, Q_{L}, for the inductor. As is known in the art, a single turn coil, such as coil 12, provides the highest quality factor for a given inductance value.

Although positioning circuit elements 16 within the area formed by coil 12 has the potential to degrade Q_{L} due to electromagnetic interference such as eddy currents, careful design layout can minimize this impact. For example, one of skill in the art will recognize that forming loops with the interconnect inside the inductor should be avoided; otherwise the inductor flux will induce current in the loop and introduce loss. Regardless, the benefits that can be achieved using the design of VCO 10 described below can outweigh any degradation cost. Further, by placing circuit elements 16 within the area defined by coil 12, significant savings in the overall area of the IC can be achieved.

The resonant frequency of LC VCO 10 depends upon the product of the inductor and capacitor values according to the following equation:

$${f}_{0} = \frac{1}{2 π \sqrt{LC}} \qquad ( 2 )$$

As such, different values can be selected for the inductor and capacitor and still achieve the same frequency fₒ. From equation (1), it can also be seen that by using a lower inductor value and a higher capacitance value to achieve a given frequency, an improvement in phase noise characteristics can be gained.

Accordingly, in a preferred embodiment, an oscillatory array 24 is formed by a complementary pair of VCOs 26 and 28 connected in parallel as depicted in FIG. 2. Each VCO 26 and 28 includes single turn inductor coils 30 and 32, respectively. Since the overall inductance of circuits in parallel is the reciprocal of the sum of the reciprocals of the individual inductances, connecting two VCOs 26 and 28 in parallel results in an overall inductance half that of each individual VCO (as VCOs 26 and 28 have the same L value). In turn, the parallel connection of capacitance is equal to the sum of the individual values, resulting in a doubling of the overall capacitance (again, as VCOs 26 and 28 have the same C value). By doubling the capacitance and halving the inductance, the resonant frequency fₒ is unchanged, but a reduction of 3 dB in phase noise is achieved.

As shown in FIG. 2, adjacent segments 34 of neighboring inductor coils 30 and 32 are preferably shared. This configuration also improves the Q_{L} of each inductor of coils 30 and 32, resulting in an additional improvement in phase noise. Depending upon the geometries of the coils, different proportions of the shared segments can be achieved. In general, configurations in which the shared segments constitute a greater percentage result in a higher Q_{L} and, correspondingly, better phase noise performance. In the embodiment comprising two VCOs shown in FIG. 2, approximately 25% of each coil 30 and 32 constitute shared segments 34. For a given VCO geometry, a greater percentage of the coil can be shared by employing multiple pairs as discussed below.

Further, as indicated in FIG. 2, the current flow in inductor coils 30 and 32 is in opposing directions, resulting in opposite flux polarity for coils 30 and 32. Due to their adjacency, each coil 30 and 32 can exploit a portion of the flux generated outside the area of the other coil that would otherwise be waster, which also increases the quality factor and reduces phase noise. Yet another benefit of this configuration is that any magnetic field interference that may be experienced by one coil is substantially cancelled since the same interference generates a phase error of the opposite polarity in the neighboring coil.

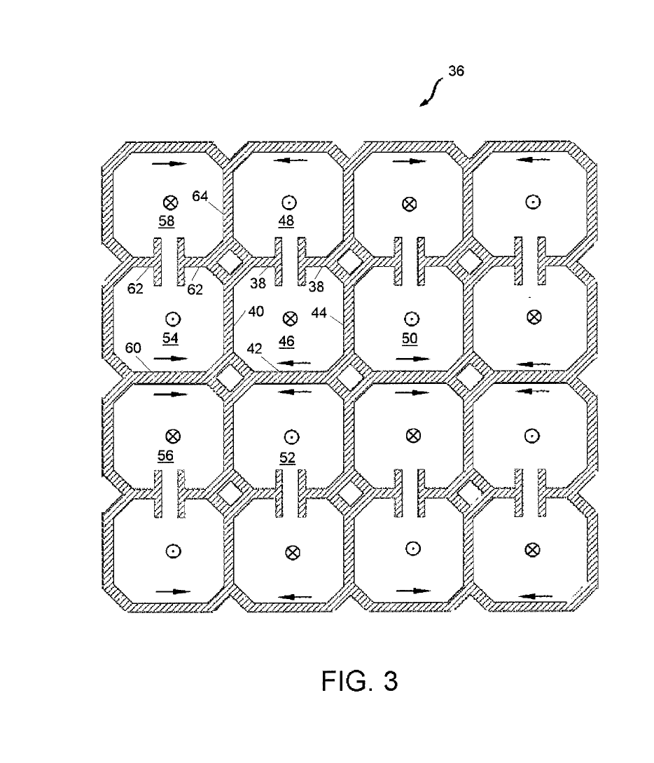

Additional improvements in phase noise can be achieved by increasing the number of VCOs connected in parallel so that multiple pairs of integrated VCOs are employed. In general, phase noise is reduced by 3 dB each time the number of VCOs is doubled. For example, FIG. 3 illustrates an array 36 of 16 VCOs in a symmetrical grid configuration. Since this represents four doublings of an individual VCO, the array 36 represents a phase noise reduction of 12 dB relative to the single VCO of FIG. 1.

Furthermore, the supplemental benefits discussed above are enhanced as the number of neighboring VCOs increase. Specifically, greater portions of each inductor coil can be shared with neighboring coils as there are neighbors on each side of the interior VCOs. For example, segments 38, 40, 42 and 44 of the inductor coil of VCO 46 are shared respectively by inductor coils of neighboring VCOs 48, 50, 52 and 54. As can be seen, the percentage of the coil that is shared for interior coils can be greater than 75% and can approach 100%. VCOs located on the edges of array 36 do not benefit as greatly, but have an improved Q_{L} as compared to a VCO that is not part of an array. Edge VCO 54 has three neighbors, VCOs 56, 46 and 58, and preferably shares coil segments 60, 40 and 62 as shown. Corner VCO 58 still receives the benefit of having two neighbors, VCOs 54 and 48, and can share coil segments 62 and 64.

As a result, the greater interactions yield an increased Q_{L} for array 36 and additional improvements in phase noise characteristics. Other configurations can also be used as desired. In an embodiment employing an array of four VCOs for example, each VCO will have two neighbors and the shared segments of the coils can be in the range of approximately 50%.

Similarly, these configurations also lead to a more efficient use of the flux generated by the coils. For example, with respect to a first VCO 46 of array 36, it is surrounded by four VCOs 48, 50, 52 and 54 having opposite flux polarity due to the indicated current flow. As such, it can exploit the excess flux generated by each of its four neighbors. Further, the excess flux produced outside VCO 46 is efficiently used by the four neighbors. Again, the benefits are not as great for the VCOs that are not located in the interior of array 36, but improvements still result. As can be seen, every VCO in array 36 has at least two neighbors having opposing flux polarity in that the edge VCOs have two neighbors and the corner VCOs have three.

Described herein are presently preferred embodiments, however, one skilled in the art that pertains to the present invention will understand that the principles of this disclosure can be extended easily with appropriate modifications to other applications. For example, any number of suitable combinations of VCO pairs can be employed to achieve a desired level of phase noise. Further, different coil geometries can be used as desired to increase mutual interactions between the VCOs of the array to improve the overall quality factor and corresponding reduce phase noise.

What is claimed is:

1. An oscillatory array comprising a first pair of integrated VCOs wherein each VCO includes resonant circuit elements and an inductor formed from a single turn coil positioned on a substantially planar substrate and wherein the VCOs are connected in parallel.

2. The oscillatory array of claim 1, wherein each of the first pair of VCOs are positioned adjacent each other in the same plane.

3. The oscillatory array of claim 2, wherein at least one segment of the single turn coil of each VCO is shared.

4. The oscillatory array of claim 3, wherein the shared segment portion of the single turn coil is at least approximately 25% of each single turn coil.

5. The oscillatory array of claim 1, wherein the substrate comprises a semiconductor.

6. The oscillatory array of claim 5, wherein the resonant circuit elements of each VCO are positioned within an area defined by the single turn coil of each VCO and substantially within the same plane.

7. The oscillatory array of claim 6, further comprising a plurality of interconnects formed in a lower metal layer of the semiconductor substrate underneath the single turn coil of each VCO and wherein the interconnects are in electrical communication with the resonant circuit elements of each VCO.

8. The oscillatory array of claim 1, wherein the first pair of VCOs have opposing flux polarities.

9. The oscillatory array of claim 3, further comprising a second pair of VCOs, wherein each VCO of the second pair includes resonant circuit elements and an inductor formed from a single turn coil positioned on the substantially planar substrate positioned adjacent the first pair of VCOs in substantially the same plane and wherein the second pair of VCOs are connected in parallel with the first pair of VCOs.

10. The oscillatory array of claim 9, wherein segments of the single turn coils of the first pair of VCOs are shared with segments of the single turn coils of the second pair of VCOs.

11. The oscillatory array of claim 10, wherein the shared segment portion of the single turn coil is at least approximately 50% of each single turn coil.

12. The oscillatory array of claim 9, wherein the resonant circuit elements of each VCO of the second pair are positioned within an area defined by the single turn coil of each VCO and substantially within the same plane.

13. The oscillatory array of claim 9, wherein each VCO of the first pair and the second pair has at least two neighboring VCOs having opposing flux polarities.

14. An oscillatory array comprising multiple integrated VCOs wherein each VCO includes resonant circuit elements and an inductor formed from a single turn coil positioned on a substantially planar substrate and wherein the VCOs are connected in parallel.

15. The oscillatory array of claim 14, comprising 16 VCOs.

16. The oscillatory array of claim 14, wherein the VCOs are positioned adjacent one another in a symmetrical grid configuration.

17. The oscillatory array of claim 16, wherein each VCO shares at least one segment of the single turn coil with at least one segment of the single turn coil of at least two neighboring VCOs.

18. The oscillatory array of claim 17, wherein at least one VCO shares at least one segment of the single turn coil with at least one segment of the single turn coil of at least four neighboring VCOs.

19. The oscillatory array of claim 18, wherein the shared segment portion of the at least one VCO is at least approximately 25% of the single turn coil.

20. The oscillatory array of claim 16, wherein each VCO has at least two neighboring VCOs having opposing flux polarities.

21. The oscillatory array of claim 20, wherein at least one VCO has at least four neighboring VCOs having opposing flux polarities.
